(19) United States
(12) Patent Application Publication
(10) Pub. No.: US 2024/0113212 A1
(43) Pub. Date: Apr. 4, 2024

(54) TECHNOLOGIES FOR PEROVSKITE TRANSISTORS

(71) Applicant: Intel Corporation, Santa Clara, CA (US)

(72) Inventors: Ian Alexander Young, Olympia, WA (US); Dmitri Evgenievich Nikonov, Beaverton, OR (US); Marko Radosavljevic, Portland, OR (US); Matthew V. Metz, Portland, OR (US); John J. Plombon, Portland, OR (US); Raseong Kim, Portland, OR (US); Kevin P. O'Brien, Portland, OR (US); Scott B. Clendenning, Portland, OR (US); Tristan A. Tronic, Aloha, OR (US); Dominique A. Adams, Portland, OR (US); Carly Rogan, North Plains, OR (US); Hai Li, Portland, OR (US); Arnab Sen Gupta, Hillsboro, OR (US); Gauri Auluck, Hillsboro, OR (US); I-Cheng Tung, Hillsboro, OR (US); Brandon Holybee, Portland, OR (US); Rachel A. Steinhardt, Beaverton, OR (US); Punyashloka Debashis, Hillsboro, OR (US)

(73) Assignee: Intel Corporation, Santa Clara, CA (US)

(21) Appl. No.: 17/956,296

(22) Filed: Sep. 29, 2022

(51) Int. Cl. H01L 29/775; H01L 21/02; H01L 21/465; H01L 29/06; H01L 29/24; H01L 29/423; H01L 29/49; H01L 29/66

(52) U.S. Cl. CPC H01L 29/775; H01L 21/02565; H01L 21/02603; H01L 21/465; H01L 29/0673; H01L 29/24; H01L 29/42392; H01L 29/4908; H01L 29/66969

(57) ABSTRACT

Technologies for a field effect transistor (FET) with a ferroelectric gate dielectric are disclosed. In an illustrative embodiment, a perovskite stack is grown on a buffer layer as part of manufacturing a transistor. The perovskite stack includes one or more doped semiconductor layers alternating with other lattice-matched layers, such as undoped semiconductor layers. Growing the doped semiconductor layers on lattice-matched layers can improve the quality of the doped semiconductor layers. The lattice-matched layers can be preferentially etched away, leaving the doped semiconductor layers as fins for a ribbon FET. In another embodiment, an interlayer can be deposited on top of a semiconductor layer, and a ferroelectric layer can be deposited on the interlayer. The interlayer can bridge a gap in lattice parameters between the semiconductor layer and the ferroelectric layer.

### BACKGROUND

Transistors are ubiquitous devices present in virtually all electronic devices. As the density of transistors continues to increase, the power dissipated by the transistors needs to be addressed. The power dissipated can be removed by heat sinks or cold plates. The power dissipation of a transistor can be reduced in several ways, such as reducing leakage current and reducing the threshold voltage of the transistor.

A typical transistor can maintain its state when a voltage is maintained at a gate electrode. However, a ferroelectric field-effect transistor (FEFET) can maintain its state based on a state of a ferroelectric layer in the transistor. FEFETs typically have a relatively high threshold voltage and a corresponding relatively high leakage current.

### BRIEF DESCRIPTION OF THE DRAWINGS

FIG. 1 is an isometric view of a ribbon field-effect transistor (FET) with spacers between fins of the ribbon FET.

FIG. 2 is a top view of the transistor of FIG. 1.

FIG. 3 is a cross-sectional side view of the transistor of FIG. 1.

FIG. 4 is a simplified flow diagram of at least one embodiment of a method for creating a ribbon FET transistor with spacers between fins of the ribbon FET.

FIG. 5 is a cross-sectional side view at one step of manufacturing the transistor of FIG. 1.

FIG. 6 is a cross-sectional side view at one step of manufacturing the transistor of FIG. 1.

FIG. 7 is a cross-sectional side view at one step of manufacturing the transistor of FIG. 1.

FIG. 8 is a cross-sectional side view at one step of manufacturing the transistor of FIG. 1.

FIG. 9 is an isometric view of a FET with an interlayer between a channel layer and a ferroelectric layer.

FIG. 10 is a top view of the transistor of FIG. 9.

FIG. 11 is a cross-sectional side view of the transistor of FIG. 9.

FIG. 12 is a cross-sectional side view of a sample showing different types of thin film lattice matching and strain relaxation.

FIG. 13 is a top-down view of a thin film grown on a substrate with a rotated lattice orientation.

FIG. 14 is a cross-sectional side view of a stack usable in a ribbon FET.

FIG. 15 is a simplified flow diagram of at least one embodiment of a method for creating a FET transistor with an interlayer between a channel layer and a ferroelectric layer.

FIG. 16 is a top view of a wafer and dies that may be included in a microelectronic assembly, in accordance with any of the embodiments disclosed herein.

FIG. 17 is a cross-sectional side view of an integrated circuit device that may be included in a microelectronic assembly, in accordance with any of the embodiments disclosed herein.

FIGS. 18A-18D are perspective views of example planar, FinFET, gate-all-around, and stacked gate-all-around transistors.

FIG. 19 is a cross-sectional side view of an integrated circuit device assembly that may include a microelectronic assembly, in accordance with any of the embodiments disclosed herein.

FIG. 20 is a block diagram of an example electrical device that may include a microelectronic assembly, in accordance with any of the embodiments disclosed herein.

### DETAILED DESCRIPTION

In one embodiment disclosed herein, as described in more detail below, the channel of a field-effect transistor (FET) is barium stannate (BaSnO₃), at least part of which is doped with lanthanum. A ribbon FET may have several fins arranged in a vertical stack. In order to create high-quality barium stannate fins, a stack of alternating doped and undoped layers of barium stannate are interleaved on a substrate. The undoped barium stannate can be partially etched away while leaving more of the doped barium stannate, creating high-quality fins of doped barium stannate. Other components of the ribbon FET, such as a dielectric layer that is ferroelectric and a gate, can be formed around the barium stannate fins. Additional embodiments with different materials for the channel and/or the spacer layers are described below. As used herein, a dielectric material includes a linear dielectric material, a paraelectric material, or a ferroelectric material.

In another embodiment, a FEFET may have a ferroelectric layer with a lattice constant that does not match that of the channel. In some cases, the strain of such a ferroelectric layer grown directly on the channel would result in the polarization of the ferroelectric layer being in the plane of the ferroelectric layer instead of perpendicular to it. In order to change the strain on the ferroelectric layer, an interlayer is used to bridge the lattice mismatch. In some embodiments, the interlayer may have a smaller lattice constant that that of the channel, more closely matching that of the ferroelectric layer. In other embodiments, the interlayer may facilitate a lattice orientation of the ferroelectric layer that is rotated relative to the channel layer, as described in more detail below. Such an approach to depositing a ferroelectric layer on a channel layer may be used for any suitable transistor configuration, such as a top gate device, a fin FET, a ribbon FET, etc. The crystalline structure of the channel and the ferroelectric are both perovskite or lattice matched to perovskite. The similarity of the ferroelectric and channel materials can reduce lattice defects, reduce trapped charges, reduce oxygen vacancies, and/or reduce polycrystalline or amorphous structure. As a result, the transistor performance can be increased, and the threshold voltage and leakage current can be reduced.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate, and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

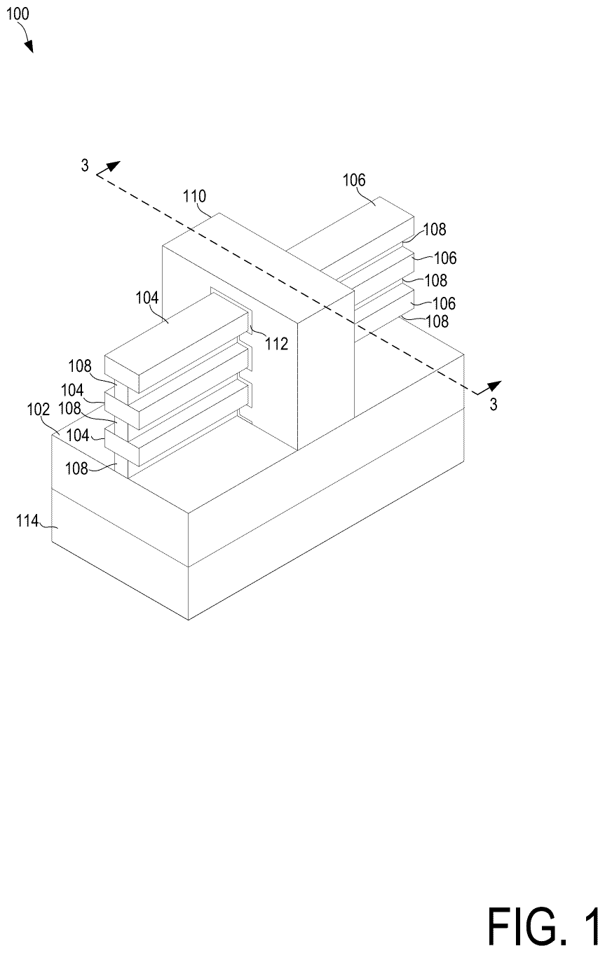

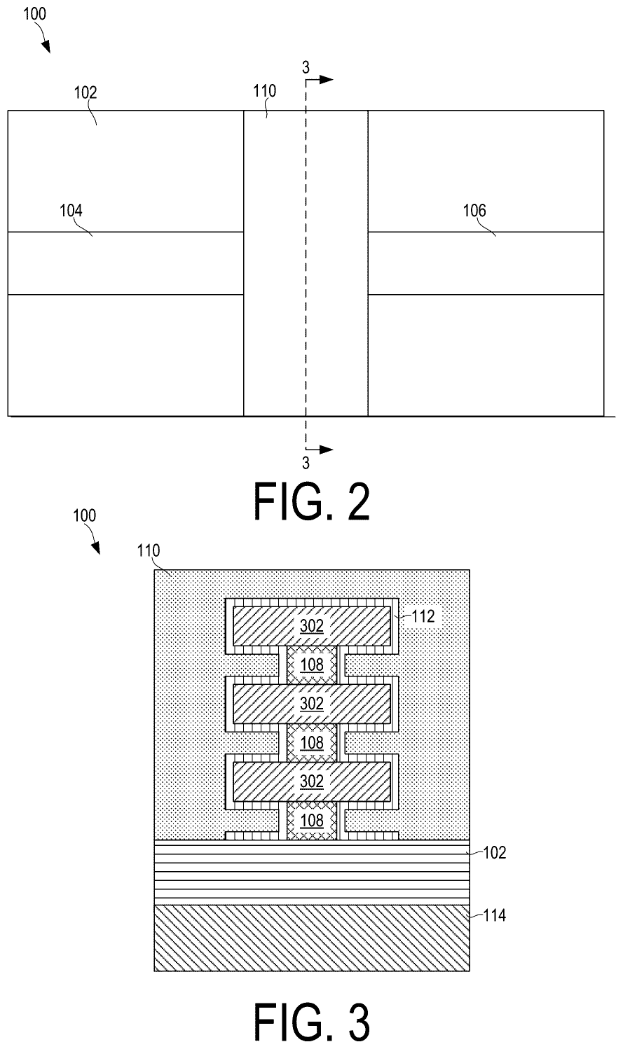

Referring now to FIGS. 1-3, in one embodiment, FIG. 1 shows a perspective view of a ribbon FET 100, FIG. 2 shows a top-down view of the ribbon FET 100, and FIG. 3 shows a cross-sectional view of the ribbon FET 100. The ribbon FET 100 may also be referred to as a gate-all-around transistor, a nanowire transistor, a nanosheet transistor, etc. The ribbon FET 100 has one or more source fins 104 and one or more drain fins 106. Spacers 108 may be interleaved with the fins 104, 106. A ferroelectric layer 112 surrounds a channel region 302 of the fins 104, 106 (see FIG. 3). A gate 110 surrounds the ferroelectric layer 112.

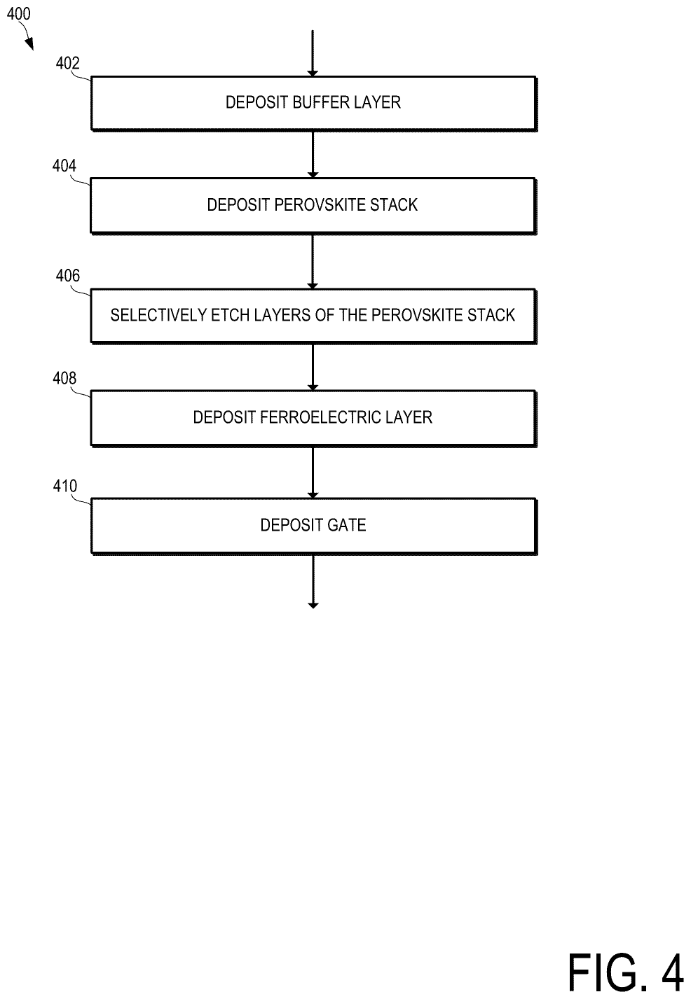

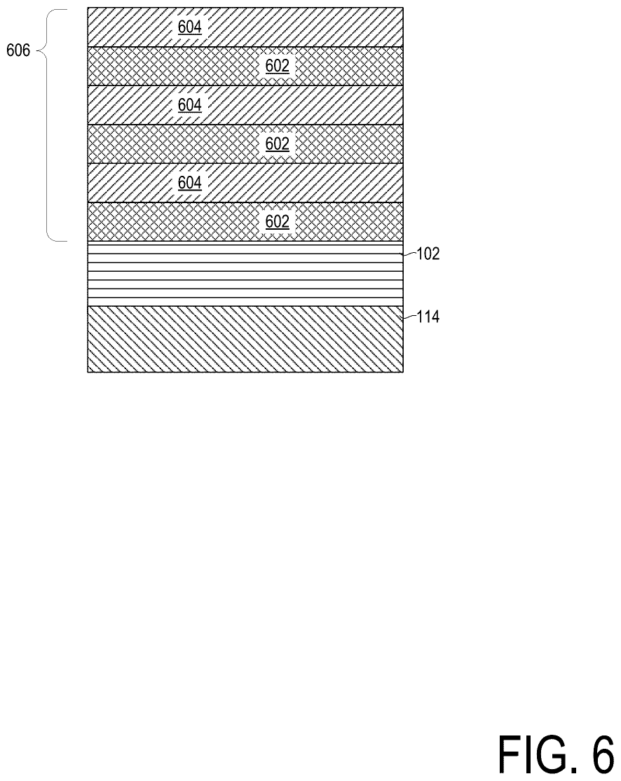

In the illustrative embodiment and as described below in more detail in regard to FIG. 4, the source fins 104, the drain fins 106, and the channel 302 are made of a doped semiconductor, and the spacers 108 are made from the same semiconductor without doping or are made from an insulator. The source fins 104, the drain fins 106, the channel 302, and the spacer 108 may be grown in alternating layers as a stack, as shown in FIG. 6. The alternation of layers of similar material allows for growth of high-quality crystals, leading to high electron mobility. The undoped semiconductor or insulator can be preferentially etched, forming the fins 104, 106 and leaving spacers 108.

In use, a voltage can be applied to the gate 110, which causes an electric field to be applied to the ferroelectric layer 112 and to the channel 302. In the illustrative embodiment, if the applied voltage causes an electric field above a coercive field, the direction of the spontaneous polarization of the ferroelectric material can switch. The electric displacement of the ferroelectric material is the spontaneous polarization of the ferroelectric when no electric field is applied by the gate 110. Under the applied field from the voltage of the gate 110, the electric displacement of the ferroelectric material increases. As a result, the electric displacement applied to the channel 302 is affected by the polarization state of the ferroelectric material of the ferroelectric layer 112, and, therefore, the current through the channel 302 is affected by the polarization state of the ferroelectric material of the ferroelectric layer 112. This property can be used to facilitate low-threshold switching, single transistor memory, and compute-in-memory.

The substrate 114 supports the buffer layer 102 and the rest of the transistor 100. In the illustrative embodiment, the substrate 114 is silicon. In other embodiments, the substrate 114 may be, e.g., silicon oxide, gallium nitride, a perovskite, etc.

A perovskite material is any crystalline material with a crystal structure similar to calcium titanate (CaTiO₃), typically with the chemical formula of ABX₃, where A is one element, B is a second element, and X is a third element. In some cases, some of one (or more) of element A, B, or X in a perovskite material may be replaced by a different element. For example, in one embodiment, Pb(ZrₓTi₁₋ₓ)O₃ (i.e., lead zirconate titanate or PZT) can have both zirconium and titanium as element B, with a varying amount of each depending on the value of x. A perovskite material may have various cation pairings, such as A⁺B²⁺X⁻₃, A²⁺B⁴⁺X²⁻₃, A³⁺B³⁺X²⁻₃, or A⁺B⁵⁺X²⁻₃.

The buffer layer 102 may be any suitable material on which the spacers 108 and/or the fins 104, 106 may be grown. The buffer layer 102 may be lattice matched to the lattice parameter of the spacers 108 and/or the fins 104, 106. In the illustrative embodiment, the buffer layer 102 is strontium titanium oxide (SrTiO₃ or STO or strontium titanate).

The source fins 104, the drain fins 106, and the channel 302 may be made from any suitable material, such as a doped perovskite. In the illustrative example, the source fins 104, the drain fins 106, and the channel 302 are made from lanthanum-doped barium stannate (La—BaSnO₃). In other embodiments, the source fins 104, the drain fins 106, and the channel 302 may be made from other materials, such as lanthanum-doped SrSnO₃ or lanthanum-doped (BaSr)SnO₃. In some embodiments, additionally or alternatively, the source fins 104, the drain fins 106, and the channel 302 may be doped with a different element, such as Nd, Ce, Cs, Y, V, K, Co, etc. The source fins 104 and drain fins 106 may be doped relatively strongly, and the channel 302 may be doped relatively lightly. In the illustrative embodiment, the transistor 100 is symmetric, and there is no functional distinction between the source 104 and the drain 106. The source fins 104, the drain fins 106, and the channel 302 may have any suitable dimensions, such as a thickness or width of, e.g., 0.5-20 nanometers and a length of, e.g., 2-50 nanometers. The transistor may include and suitable number of source fins 104 and drain fins 106, such as 1-5.

The spacers 108 may be made from any material with a lattice parameter that is close to that of the source fins 104, the drain fins 106, and the channel 302, such as a lattice parameter within 3% of the source fins 104, the drain fins 106, and the channel 302. In the illustrative embodiment, the source fins 104, the drain fins 106, and the channel 302 are made from a doped material (e.g., lanthanum-doped barium stannate), and the spacers 108 are made from the corresponding undoped material (e.g., undoped barium stannate). In other embodiments, the source fins 104, the drain fins 106, and the channel 302 may be lanthanum-doped barium stannate, and the layers 108 may be made from, e.g., relatively lightly doped barium stannate (BaSnO₃), SrTiO₃, SrRuO₃, (SrBa)RuO₃, ReScO₃ (where Re may be Dy, Tb, Gd, Eu, Sm, Nd, Pr, Ce, or La), LaLuO₃, La(LuSc)O₃, BaHfO₃, BaZrO₃, LaAlO₃, LaCoO₃, SrSnO₃, Ba₂ScNbO₆, SrZrO₃, SrHfO₃, LaInO₃, MgO, (Sr,Ba)SnO₃, etc. In some embodiments, the spacers 108 may be a material with a lattice constant that applies a small amount of tensile strain on the source fins 104, the drain fins 106, and the channel 302, which may increase electron mobility.

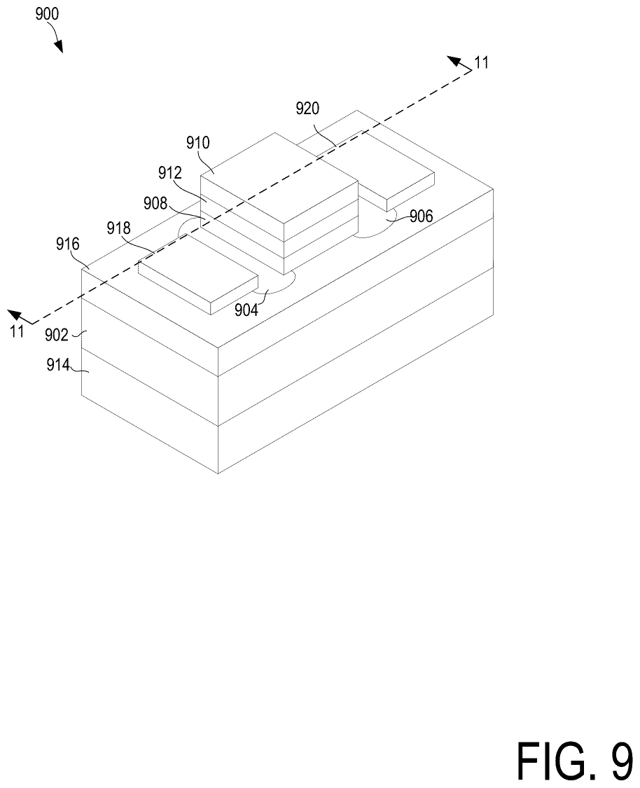

The ferroelectric layer 112 may be any suitable ferroelectric, such as a perovskite ferroelectric. In the illustrative embodiment, the ferroelectric layer 112 may be barium titanate (BaTiO₃ or BTO) or bismuth ferrite (BiFeO₃ or BFO). In other embodiments, the ferroelectric layer 112 may be a different material, such as lead zirconate titanate (Pb(ZrₓTi₁₋ₓ)O₃ or PZT), lead niobate zirconate titanate ((Pb₁₋ₓNbₓ)(Zr_{1-y}Ti_{y})O₃ or PNZT), lead lanthanum zirconate titanate ((Pb₁₋ₓLaₓ)(Zr_{1-y}Ti_{y})O₃ or PLZT), lanthanum bismuth ferrite (LaₓBi₁₋ₓFeO₃ or LaBFO), bismuth iron cobaltate (BiFe₁₋ₓCoₓO₃), lithium or potassium niobate (LiNbO₃ or KNbO₃), CaNbTi₂O₆, Pb₂BiNbO₆, Ca₃Nb₂N₂O₅, Bi₄Ti₃O₁₂, Ba(Hf,Ti)O₃, (Ba,Ca)(ZrTi)O₃, GdFeO₃, (Gd,La)FeO₃, etc. In some embodiments, an interlayer may be between the channel 302 and the ferroelectric layer 112, as described below in regard to FIGS. 9-11.

The ferroelectric layer 112 may have any suitable coercive field, such as 50-500 kV/cm. The ferroelectric layer 112 may be any suitable thickness. The ferroelectric layer 112 may have any suitable thickness, such as a thickness of about 0.5-25 nanometers.

The threshold voltage of the transistor 100 depends on the ferroelectric layer 112 material as well as the channel 302 thickness and doping concentration. The threshold voltage of the transistor 100 may be any suitable value, such as 0.2-5 volts, depending on the materials used.

In some embodiments, the polarization of the ferroelectric of the ferroelectric layer 112 switches all at once in a few picoseconds. In other embodiments, the ferroelectric of the ferroelectric layer 112 may have multiple domains that may switch at different applied electric fields (and, therefore, at different times). In such embodiments, the ferroelectric of the ferroelectric layer 112 may have multiple stable states that can be set by applying a particular voltage to the gate 110. Such a transistor 100 can act as a multi-level memory or like an analog memory.

The illustrative gate 110 is a metallic perovskite, such as strontium ruthenate (SrRuO₃ or SRO), lanthanum strontium manganite (La₁₋ₓSrₓMnO₃ or LSMO), lanthanum strontium cobalt oxide (La₁₋ₓSrₓCoO₃ or LSCO), SrVO₃, SrCrO₃, SrFeO₃, ReO₃, CaRuO₃, SrMoO₃, SrNbO₃, LaNiO₃, etc. In other embodiments, the gate 110 may be other materials, such as platinum, iridium, copper, aluminum, or other metal, oxides with high electric conductivity that do not have the perovskite structure including RuO₂, IrO₂, and ITO, polysilicon, etc. In some embodiments, the work function of the gate 110 is selected to shift the coercive voltage across the ferroelectric layer 112.

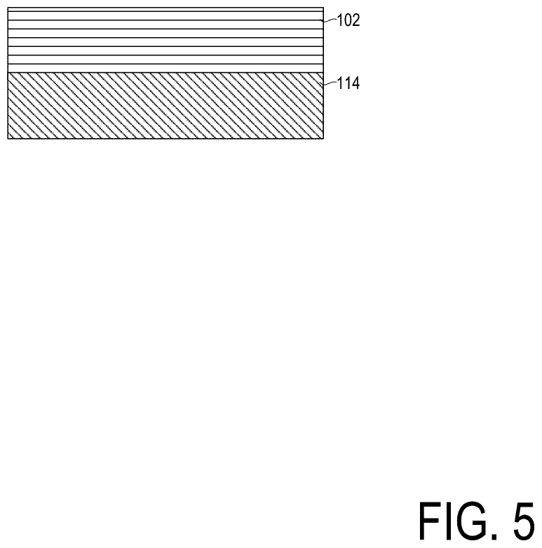

Referring now to FIG. 4, in one embodiment, a flowchart for a method 400 for creating a transistor (such as transistor 100) is shown. The method 400 may be executed by a technician and/or by one or more automated machines. In some embodiments, one or more machines may be programmed to do some or all of the steps of the method 400. Such a machine may include, e.g., a memory, a processor, data storage, etc. The memory and/or data storage may store instructions that, when executed by the machine, causes the machine to perform some or all of the steps of the method 400. The method 400 may use any suitable set of techniques that are used in semiconductor processing, such as chemical vapor deposition, atomic layer deposition, physical vapor deposition, molecular beam epitaxy, pulsed laser deposition, layer transfer, photolithography, ion implantation, dry etching, wet etching, thermal treatments, etc. FIGS. 5-8 show various stages of the method 400 as it is used to create a transistor.

The method 400 begins in block 402, in which a buffer layer 102 is deposited on a substrate 114, as shown in FIG. 5. The buffer layer 102 may be deposited in any suitable manner, such as chemical vapor deposition, atomic layer deposition, physical vapor deposition, molecular beam epitaxy, pulsed laser deposition, etc. In some embodiments, the buffer layer 102 is deposited using layer transfer.

In block 404, a perovskite stack 606 is applied. In the illustrative embodiment, the perovskite stack 606 includes alternating layers of lanthanum-doped barium stannate layers 604 and undoped barium stannate layers 602. In some embodiments, different parts of the lanthanum-doped barium stannate layers 604 may have different densities of dopants. For example, the regions of the lanthanum-doped barium stannate layers 604 that will become source fins 104 and drain fins 106 may have a higher dopant concentration, and layers that will become the channel 302 may have a lower dopant concentration. In other embodiments, the stack 606 may include lanthanum-doped barium stannate layers 604 alternating with layers 602 made from, e.g., relatively lightly doped barium stannate (e.g., 0-20% of the dopant concentration as the layers 604), SrTiO₃, SrRuO₃, (SrBa)RuO₃, ReScO₃ (where Re may be Dy, Tb, Gd, Eu, Sm, Nd, Pr, Ce, or La), LaLuO₃, La(LuSc)O₃, BaHfO₃, BaZrO₃, LaAlO₃, LaCoO₃, SrSnO₃, Ba₂ScNbO₆, SrZrO₃, SrHfO₃, LaInO₃, MgO, (Sr,Ba)SnO₃, etc. In the illustrative embodiment, the lattice parameter for the layers 604 closely matches that for the layers 602. As such, the layers 604 can be grown as high-quality crystals with relatively few defects and high electron mobility. In some embodiments, the layers 602 may be a material with a lattice constant that applies a small amount of tensile strain on the layers 604, which may increase electron mobility in the layers 604. The layers 602, 604 may be grown in any suitable manner, such as chemical vapor deposition, atomic layer deposition, physical vapor deposition, molecular beam epitaxy, pulsed laser deposition, etc. In some embodiments, the stack 606 may include one, some, or all layers that are not perovskites.

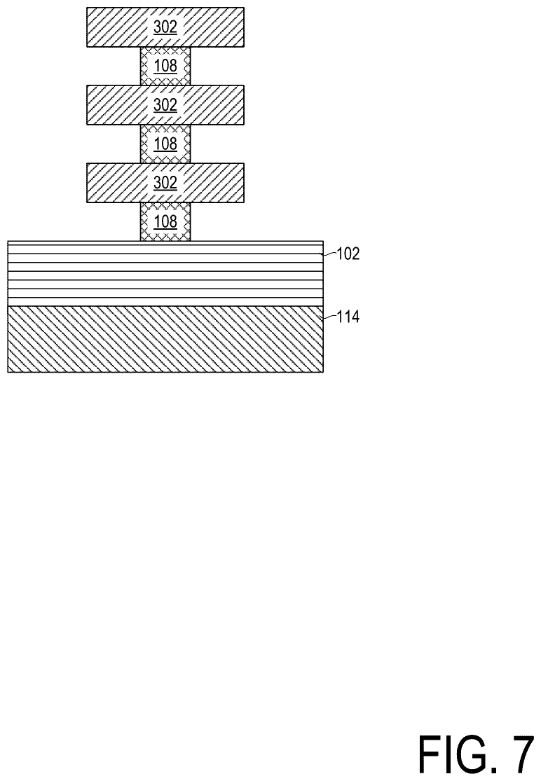

In block 406, the layers 602 are preferentially etched while leaving more or substantially all of the layers 604 intact, resulting in the structure shown in FIG. 7. At the point where the cross-section is taken, the layers 604 will be used as the channel 302. At other points, a cross-section may show where the layers 604 will be used as source fins 104 or drain fins 106. In the illustrative embodiment, the layers 602 are etched with, e.g., hydrogen fluoride. If the layers 602 are undoped barium stannate and the layers 604 are lanthanum-doped barium stannate, the lanthanum may slow the etching rate for the layers 604, allowing the layers 602 to be preferentially etched. In other embodiments, a different etchant or etching technique may be used to preferentially remove the layers 602.

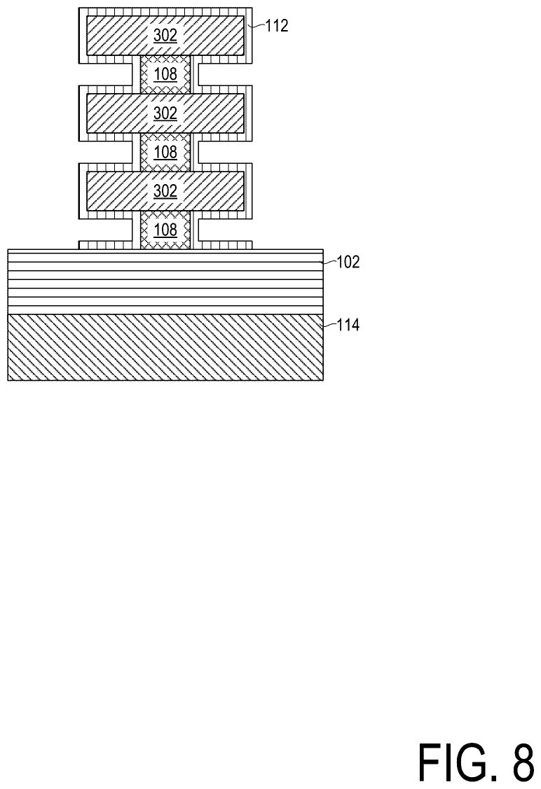

In block 408, the ferroelectric layer 112 is deposited on the channel 302, the source fins 104, the drain fins 106, and the layers 108, as shown in FIG. 8. In the illustrative embodiment, the ferroelectric layer 112 may be barium titanate (BaTiO₃ or BTO) or bismuth ferrite (BiFeO₃ or BFO). In other embodiments, the ferroelectric layer 112 may be a different material, such as lead zirconate titanate (Pb(ZrₓTi₁₋ₓ)O₃ or PZT), lead niobate zirconate titanate ((Pb₁₋ₓNbₓ)(Zr_{1-y}Ti_{y})O₃ or PNZT), lead lanthanum zirconate titanate ((Pb₁₋ₓLaₓ)(Zr_{1-y}Ti_{y})O₃ or PLZT), lanthanum bismuth ferrite (LaₓBi₁₋ₓFeO₃ or LaBFO), bismuth iron cobaltate (BiFe₁₋ₓCoₓO₃), lithium or potassium niobate (LiNbO₃ or KNbO₃), CaNbTi₂O₆, Pb₂BiNbO₆, Ca₃Nb₂N₂O₅, Bi₄Ti₃O₁₂, (BaSr)TiO₃, Ba(ZrTi)O₃, Ba(Hf,Ti)O₃, (Ba,Ca)(ZrTi)O₃, GdFeO₃, (Gd,La)FeO₃, etc. In some embodiments, an interlayer may be deposited first, which may affect the polarization of the ferroelectric layer 112, as described in more detail below in regard to FIGS. 9-11.

In block 410, a gate 110 is deposited over the ferroelectric layer 112, as shown in FIGS. 1-3. The illustrative gate 110 is a metallic perovskite, such as strontium ruthenate (SrRuO₃ or SRO), lanthanum strontium manganite (La₁₋ₓSrₓMnO₃ or LSMO), lanthanum strontium cobalt oxide (La₁₋ₓSrₓCoO₃ or LSCO), SrVO₃, SrCrO₃, SrFeO₃, ReO₃, CaRuO₃, SrMoO₃, SrNbO₃, LaNiO₃, etc. In other embodiments, the gate 110 may be other materials, such as platinum, iridium, copper, aluminum, or other metal, oxides with high electric conductivity that do not have the perovskite structure including RuO₂, IrO₂, and ITO, polysilicon, etc.

It should be appreciated that the method 400 is one of many possible embodiments of manufacturing the transistor 100. Different approaches or orders of steps are envisioned as well. The steps of the method 400 may be done in a different order or the method 400 may include different steps for different embodiments of the transistor 100. It should be appreciated that a complete manufacturing process of an integrated circuit that includes the transistor 100 may include steps not shown in the method 400, such as cleaning, surface passivation, creating interconnects, packaging, etc. In some embodiments, the layers 602 may be fully removed around the channel 302, allowing the gate 110 to wrap around the channel 302 more fully. In some embodiments, the layers 602 may be fully removed around the source fins 104 and drain fins 106 as well as the channel 302. In such embodiments, one or more other layers may support the source fins 104, the channel 302, and the drain fins 106 while the layers 602 are removed.

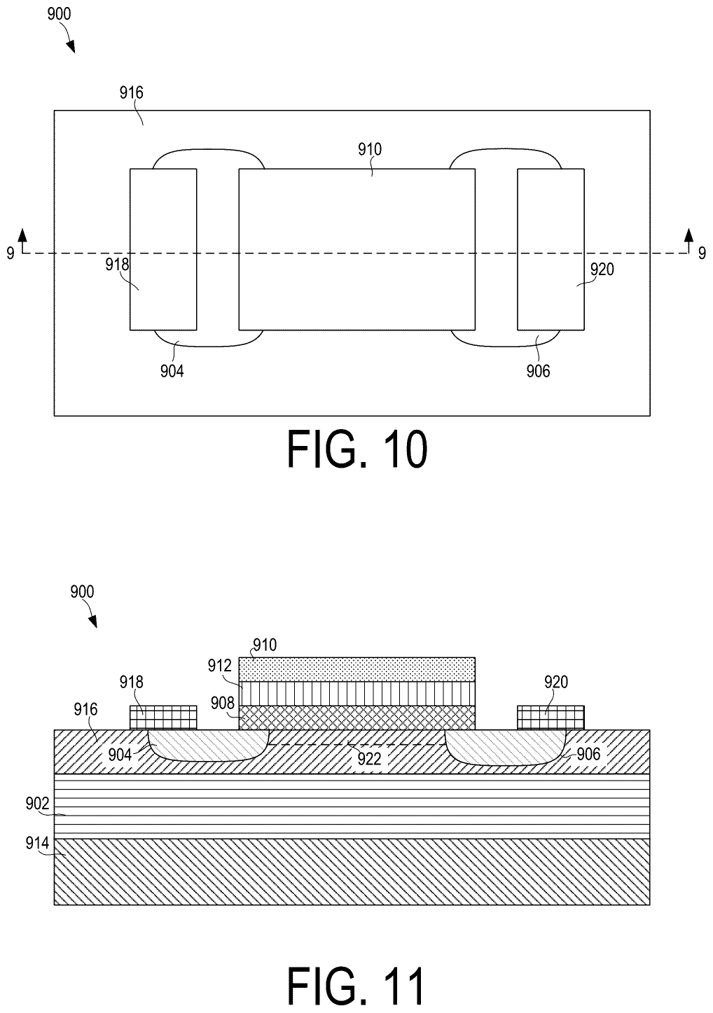

Referring now to FIGS. 9-11, in one embodiment, FIG. 9 shows a perspective view of a transistor 900, FIG. 10 shows a top-down view of the transistor 900, and FIG. 11 shows a cross-sectional view of the transistor 900. The transistor 900 is supported by a substrate 914 and a buffer layer 902. A semiconductor layer 916 is on top of the buffer layer 902. A source region 904, a drain region 906, and a channel region 922 are defined in the semiconductor layer. A source electrode 918 is positioned on top of the source region 904, and a drain electrode 920 is positioned on top of the drain region 906. On top of the channel region 922 is an interlayer 908, a ferroelectric layer 912, and a gate 910. The transistor 900 may work in a similar manner as the transistor 100, with the ferroelectric layer 912 reducing the switching voltage of the transistor 900.

In some embodiments, if the ferroelectric layer 912 is deposited directly on the semiconductor layer 916, the bulk lattice constant for the ferroelectric layer 912 may be smaller than the lattice constant of the semiconductor layer 916, putting the ferroelectric layer 912 under tensile strain forces. In some ferroelectrics, such a tensile strain force may keep the polarization of the ferroelectric layer 912 in the plane of the ferroelectric layer 912, as opposed to out of the plane, towards the channel region 922.

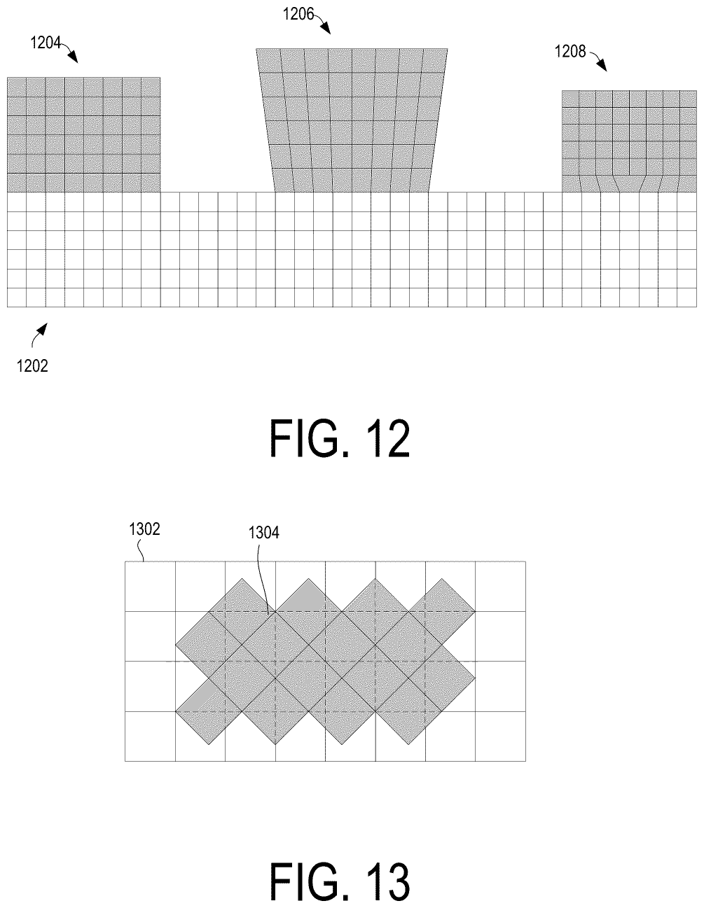

Simplified depictions of possible results of lattice mismatch are depicted in FIG. 12. A substrate crystal 1202 is used to deposit thin films. One thin film 1204 has a matching lattice constant, with no resulting strain. One thin film 1206 has a larger lattice constant than the substrate crystal 1202, leading to a strained thin film 1206. Another thin film 1208 has a smaller lattice constant but relaxes in a small number of atomic layers, leading to a relaxed thin film 1208.

In the illustrative embodiment, the interlayer 908 is deposited before the ferroelectric layer 912 to bridge the lattice mismatch between the ferroelectric layer 912 and the semiconductor layer 916. The interlayer 908 may bridge the lattice mismatch in any suitable manner. For example, in one embodiment, the interlayer 908 has a larger lattice constant than the semiconductor layer 916. The lattice constant of the interlayer 908 may be about the same (e.g., within 3%) as the ferroelectric layer 912, or the lattice constant of the interlayer 908 may be slightly smaller than that of the ferroelectric layer 912 (e.g., 1-5% smaller). When the interlayer 908 is deposited on the semiconductor layer 916, it quickly relaxes, similar to the thin film 1208 shown in FIG. 12. The ferroelectric layer 912 can then be deposited on the interlayer 908, with little to no strain or slight compressive strain, allowing the polarization of the ferroelectric layer 912 to be perpendicular to the plane of the ferroelectric layer 912.

In another example, the interlayer 908 may bridge the lattice mismatch in another manner. For example, in one embodiment, the interlayer 908 and/or the ferroelectric layer 912 may be grown at an angle relative to the underlying crystal. As shown in FIG. 13, in some cases, a thin film 1304 can grow on a substrate crystal 1302 with an orientation other than cube on cube, such as an orientation with the thin film 1304 rotated 45° and, e.g., three unit cells of the thin film 1304 can stretch across two of the lattice sites of the substrate crystal 1302, with a resulting small effective lattice mismatch.

The interlayer 908 may be deposited on the semiconductor layer 912 at a rotated angle in a similar manner, and the ferroelectric layer 912 may then be deposited on the interlayer 908, with, e.g., a small compressive lattice mismatch. In another embodiment, the interlayer 908 may be deposited on the semiconductor layer 916 in a cube-on-cube manner, and the ferroelectric layer 912 may be deposited on the interlayer 908 at a rotated angle with, e.g., a small compressive lattice mismatch.

In the illustrative embodiment, the substrate 914 is silicon. In other embodiments, the substrate 914 may be, e.g., silicon oxide, gallium nitride, a perovskite, etc. The buffer layer 902 may be any suitable material on which the spacers semiconductor layer 916 may be grown. The buffer layer 902 may be lattice matched to the lattice parameter of the semiconductor layer 916. In the illustrative embodiment, the buffer layer 902 is strontium titanium oxide (SrTiO₃ or STO or strontium titanate).

The semiconductor layer 916 may be made from any suitable material, such as a doped perovskite. In the illustrative example, the semiconductor layer 916 is made from lanthanum-doped barium stannate (La₁₋ₓBaSnO₃). The source region 904 and drain region 906 may be doped relatively strongly, and the channel 922 may be doped relatively lightly. In the illustrative embodiment, the transistor 900 is symmetric, and there is no functional distinction between the source region 904 and the drain region 906.

The ferroelectric layer 912 may be any suitable ferroelectric, such as a perovskite ferroelectric. In the illustrative embodiment, the ferroelectric layer 912 may be barium titanate (BaTiO₃ or BTO) or bismuth ferrite (BiFeO₃ or BFO). In other embodiments, the ferroelectric layer 912 may be a different material, such as lead zirconate titanate (Pb(ZrₓTi₁₋ₓ)O₃ or PZT), lead niobate zirconate titanate ((Pb₁₋ₓNbₓ)(Zr_{1-y}Ti_{y})O₃ or PNZT), lead lanthanum zirconate titanate ((Pb₁₋ₓLaₓ)(Zr_{1-y}Ti_{y})O₃ or PLZT), lanthanum bismuth ferrite (LaₓBi₁₋ₓFeO₃ or LaBFO), bismuth iron cobaltate (BiFe₁₋ₓCoₓO₃), lithium or potassium niobate (LiNbO₃ or KNbO₃), CaNbTi₂O₆, Pb₂BiNbO₆, Ca₃Nb₂N₂O₅, Bi₄Ti₃O₁₂, (BaSr)TiO₃, Ba(ZrTi)O₃, Ba(Hf,Ti)O₃, (Ba,Ca)(ZrTi)O₃, GdFeO₃, (Gd,La)FeO₃, etc.

The interlayer 908 may be any suitable material to bridge the gap between the semiconductor layer 916 and the ferroelectric layer 912. For example, in embodiments with a semiconductor layer 916 made from lanthanum-doped barium stannate and a dielectric 912 made from BTO or BFO, the lattice parameter for the semiconductor layer 916 would be 4.116 Å, higher than that for BTO (3.99 Å) or BFO (3.96 Å). The interlayer 908 may bridge the gap between the lattice parameters by having a smaller lattice parameter than that of lanthanum-doped barium stannate. For example, the interlayer 908 may be, e.g., SrTiO₃, LaAlO₃, YAlO₃, or LuAlO₃. In other embodiments, the interlayer 908 may bridge the gap between the lattice parameters by having a larger lattice parameter than that of lanthanum-doped barium stannate and being rotated relative to the crystal structure of the semiconductor layer 916. For example, the interlayer 908 may be, e.g., MgO, MgAl₂O₄, BaO, SrO, LaLuO₃, MgCr₂O₄, MgFe₂O₄, YAlO₃, or YSZ. In the illustrative embodiment, the interlayer 908 is a dielectric, such as a high-k dielectric. In some embodiments, the interlayer 908 may help reduce leakage current from the channel region 922 to the gate 910.

In the illustrative embodiment, the gate 910, the source electrode 918, and/or the drain electrode 920 is a metallic perovskite, such as strontium ruthenate (SrRuO₃ or SRO), lanthanum strontium manganite (La₁₋ₓSrₓMnO₃ or LSMO), lanthanum strontium cobalt oxide (La₁₋ₓSrₓCoO₃ or LSCO), SrVO₃, SrCrO₃, SrFeO₃, ReO₃, CaRuO₃, SrMoO₃, SrNbO₃, LaNiO₃, etc. In other embodiments, the gate 910, the source electrode 918, and/or the drain electrode 920 may be other materials, such as platinum, iridium, copper, aluminum, or other metal, oxides with high electric conductivity that do not have the perovskite structure including RuO₂, IrO₂, and ITO, polysilicon, etc. In some embodiments, the work function of the gate 910 is selected to shift the coercive voltage across the ferroelectric layer 112.

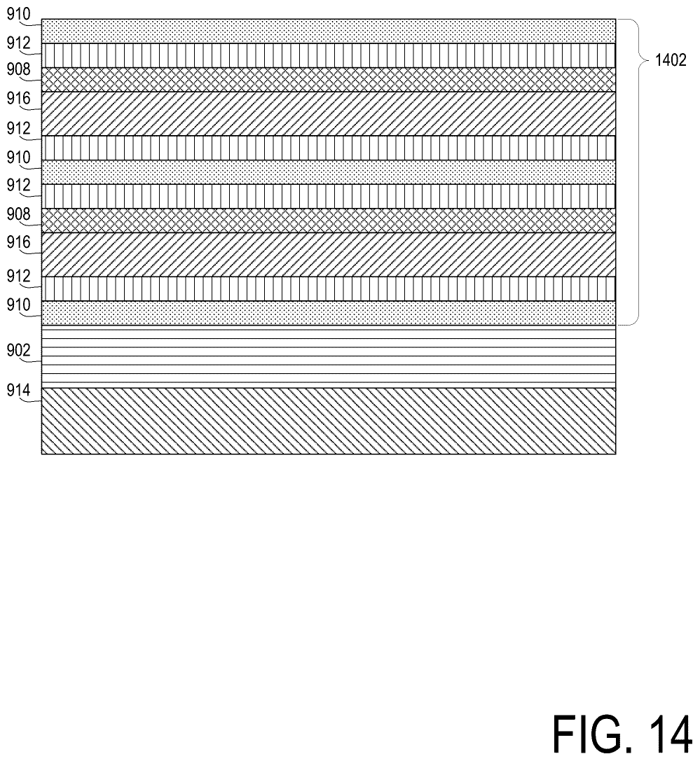

It should be appreciated that the approaches described above in regard to the top-gate transistor 900 can be similarly applied to non-planar transistors, such as finFET transistors, double-gate or tri-gate transistors, ribbon FET transistors, etc. For example, a stack 1402 may be created as part of creating a ribbon FET transistor, as shown in FIG. 14. The stack 1402 may include alternative layers of a gate 910, ferroelectric layer 912, and semiconductor layer 916. Anytime in the stack 1402 where the dielectric layer 912 is to be grown above the semiconductor layer 916, an interlayer 908 is deposited first to bridge the gap between the dielectric layer 912 and the semiconductor layer 916.

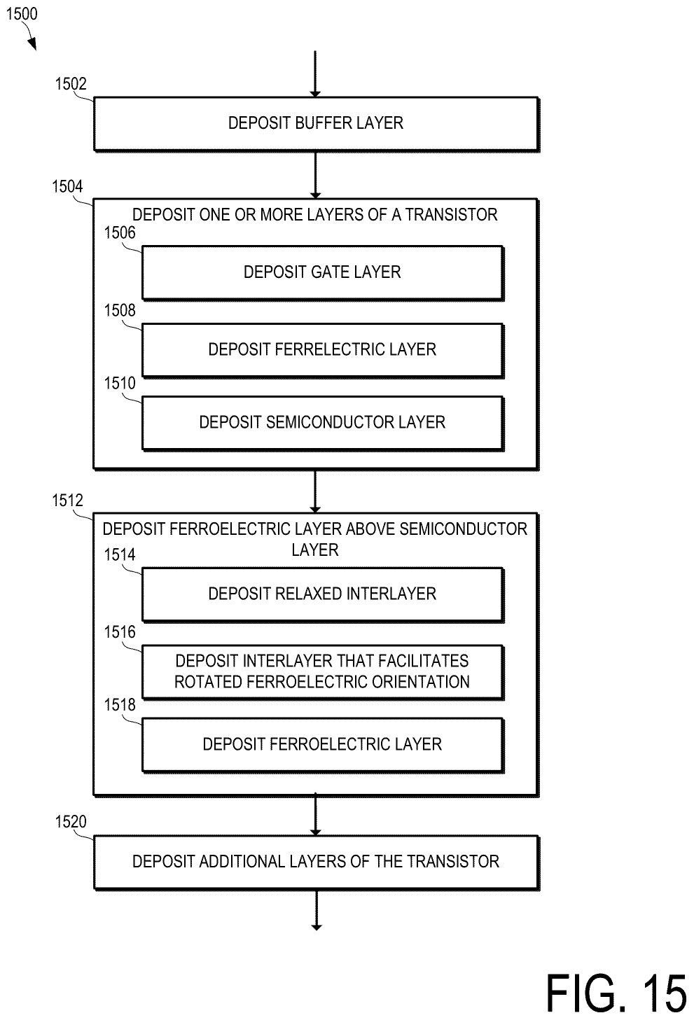

Referring now to FIG. 15, in one embodiment, a flowchart for a method 1500 for creating a transistor (such as transistor 900) is shown. The method 1500 may be executed by a technician and/or by one or more automated machines. In some embodiments, one or more machines may be programmed to do some or all of the steps of the method 1500. Such a machine may include, e.g., a memory, a processor, data storage, etc. The memory and/or data storage may store instructions that, when executed by the machine, causes the machine to perform some or all of the steps of the method 1500. The method 1500 may use any suitable set of techniques that are used in semiconductor processing, such as chemical vapor deposition, atomic layer deposition, physical vapor deposition, molecular beam epitaxy, pulsed laser deposition, layer transfer, photolithography, ion implantation, dry etching, wet etching, thermal treatments, etc.

The method 1500 begins in block 1502, in which a buffer layer 902 is deposited on a substrate 914. The buffer layer 902 may be deposited in any suitable manner, such as chemical vapor deposition, atomic layer deposition, physical vapor deposition, molecular beam epitaxy, pulsed laser deposition, etc. In some embodiments, the buffer layer 902 is deposited using layer transfer.

In block 1504, one or more layers of a transistor are deposited. For example, in one embodiment, such as for a ribbon FET, a gate 910 may be deposited on the buffer layer 902 in block 1506, and a dielectric or ferroelectric layer 912 may be deposited on the gate 910 in block 1508. In another embodiment, such as for a top gate transistor, a semiconductor layer 916 may be deposited on the buffer layer 902 in block 1510. In some embodiments, several layers, such as several layers of the stack 1402, may be applied in block 1504. In the illustrative embodiment, a ferroelectric layer 912 may be deposited directly on a gate 910 without an interlayer 908. In other embodiments, an interlayer 908 may be deposited to bridge between the lattice parameters of the semiconductor layer 916 and the ferroelectric layer 912. In the illustrative embodiment, a layer may be grown on the ferroelectric layer 912 with a lattice mismatch that does not affect the polarization of the ferroelectric layer 912. The layers may be deposited in any suitable manner, such as chemical vapor deposition, atomic layer deposition, physical vapor deposition, molecular beam epitaxy, pulsed laser deposition, etc.

In block 1512, a ferroelectric layer 912 is deposited above a semiconductor layer 916. As discussed above, in some embodiments, the ferroelectric layer 912 may have a smaller lattice parameter than the semiconductor layer 916, and, if grown directly on the semiconductor layer 916, the ferroelectric layer 912 would be under tensile strain, forcing the polarization of the ferroelectric layer 912 to be in-plane. In order to bridge the lattice mismatch, a relaxed interlayer 908 is deposited in block 1514. Additionally or alternatively, in some embodiments, an interlayer 908 may be deposited that facilitates growth of the ferroelectric layer 912 at a rotated orientation relative to the semiconductor layer 916 in block 1516. The interlayer 908 may itself be rotated relative to the semiconductor layer 916, or the interlayer 908 may allow for a rotated ferroelectric layer 912 to be grown on it. In block 1518, a ferroelectric layer 912 is deposited on the interlayer 908.

In block 1520, additional layers of the transistor may be deposited, such as additional layers of a stack 1402 or additional layers or components of a top gate transistor or ribbon FET. The various layers may be etched or otherwise processed as necessary to complete fabrication of the transistor.

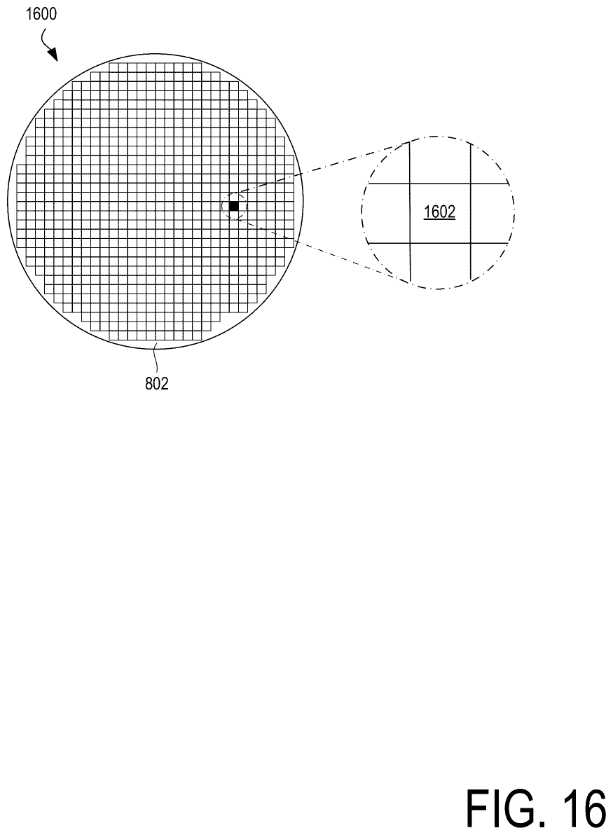

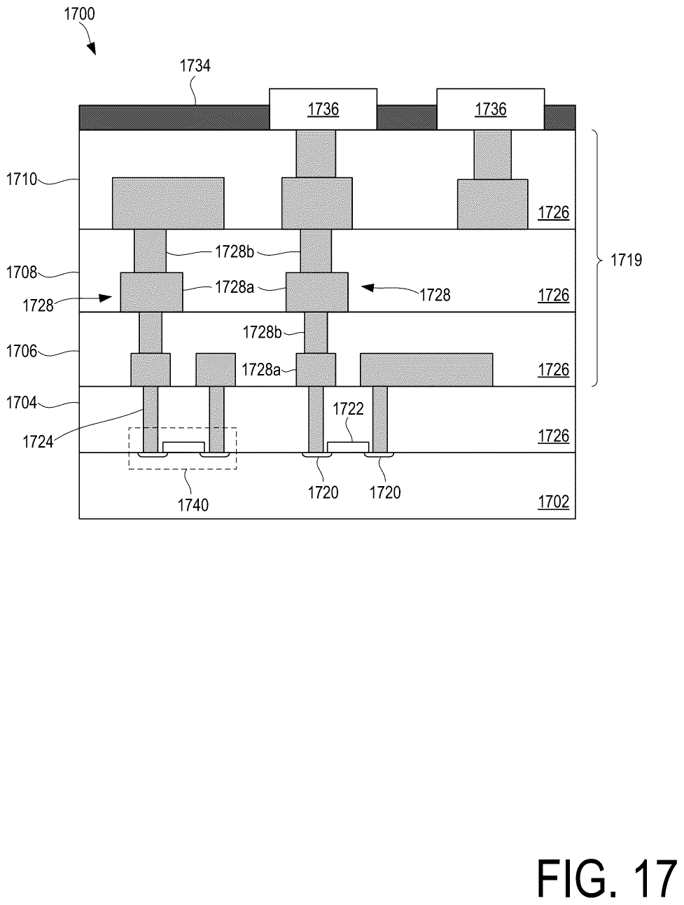

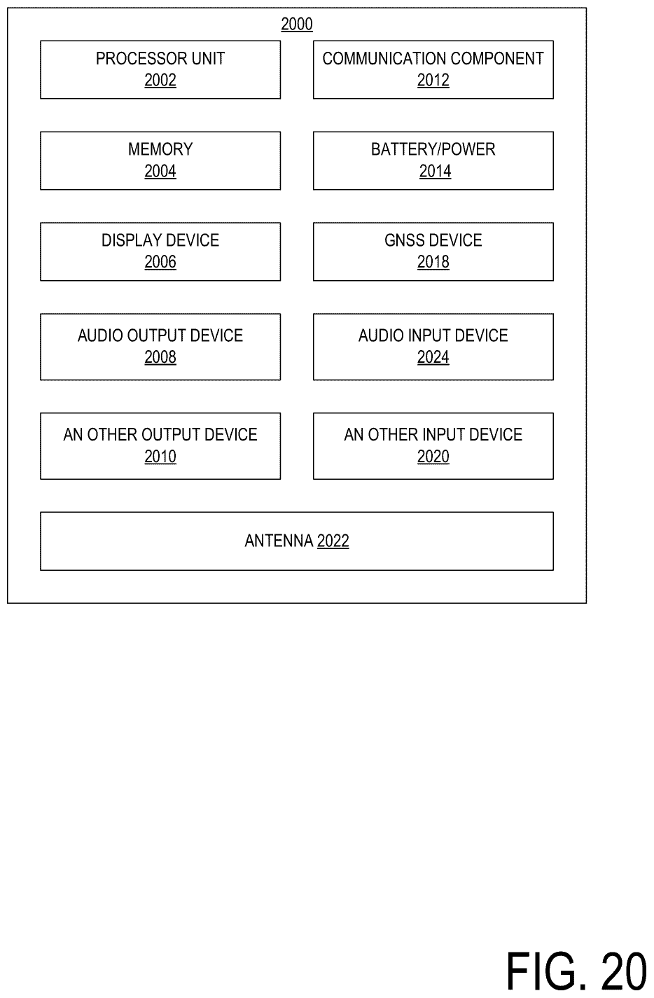

FIG. 16 is a top view of a wafer 1600 and dies 1602 that may be include in of the transistors 100, 900 disclosed herein. The wafer 1600 may be composed of semiconductor material and may include one or more dies 1602 having integrated circuit structures formed on a surface of the wafer 1600. The individual dies 1602 may be a repeating unit of an integrated circuit product that includes any suitable integrated circuit. After the fabrication of the semiconductor product is complete, the wafer 1600 may undergo a singulation process in which the dies 1602 are separated from one another to provide discrete “chips” of the integrated circuit product. The die 1602 may include one or more transistors (e.g., some of the transistors 1740 of FIG. 17, discussed below), supporting circuitry to route electrical signals to the transistors, passive components (e.g., signal traces, resistors, capacitors, or inductors), and/or any other integrated circuit components. In some embodiments, the wafer 1600 or the die 1602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1602. For example, a memory array formed by multiple memory devices may be formed on a same die 1602 as a processor unit (e.g., the processor unit 2002 of FIG. 20) or other logic that is configured to store information in the memory devices or execute instructions stored in the memory array. Various ones of the transistors 100, 900 disclosed herein may be manufactured using a die-to-wafer assembly technique in which some dies are attached to a wafer 1600 that include others of the dies, and the wafer 1600 is subsequently singulated.

FIG. 17 is a cross-sectional side view of an integrated circuit device 1700 that may include any of the transistors 100, 900 disclosed herein. One or more of the integrated circuit devices 1700 may be included in one or more dies 1602 (FIG. 16). The integrated circuit device 1700 may be formed on a die substrate 1702 (e.g., the wafer 1600 of FIG. 16) and may be included in a die (e.g., the die 1602 of FIG. 16). The die substrate 1702 may be a semiconductor substrate composed of semiconductor material systems including, for example, n-type or p-type materials systems (or a combination of both). The die substrate 1702 may include, for example, a crystalline substrate formed using a bulk silicon or a silicon-on-insulator (SOI) substructure. In some embodiments, the die substrate 1702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1702. Although a few examples of materials from which the die substrate 1702 may be formed are described here, any material that may serve as a foundation for an integrated circuit device 1700 may be used. The die substrate 1702 may be part of a singulated die (e.g., the dies 1602 of FIG. 16) or a wafer (e.g., the wafer 1600 of FIG. 16).

The integrated circuit device 1700 may include one or more device layers 1704 disposed on the die substrate 1702. The device layer 1704 may include features of one or more transistors 1740 (e.g., metal oxide semiconductor field-effect transistors (MOSFETs)) formed on the die substrate 1702. The transistors 1740 may include, for example, one or more source and/or drain (S/D) regions 1720, a gate 1722 to control current flow between the S/D regions 1720, and one or more S/D contacts 1724 to route electrical signals to/from the S/D regions 1720. The transistors 1740 may include additional features not depicted for the sake of clarity, such as device isolation regions, gate contacts, and the like. The transistors 1740 are not limited to the type and configuration depicted in FIG. 17 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

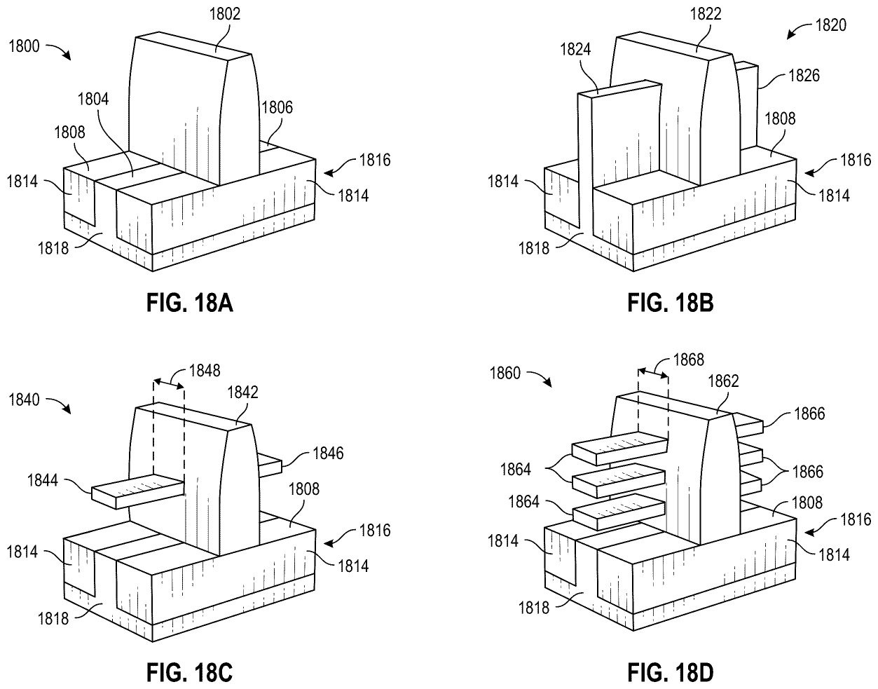

FIGS. 18A-18D are simplified perspective views of example planar, FinFET, gate-all-around, and stacked gate-all-around transistors. The transistors illustrated in FIGS. 18A-18D are formed on a substrate 1816 having a surface 1808. Isolation regions 1814 separate the source and drain regions of the transistors from other transistors and from a bulk region 1818 of the substrate 1816.

FIG. 18A is a perspective view of an example planar transistor 1800 comprising a gate 1802 that controls current flow between a source region 1804 and a drain region 1806. The transistor 1800 is planar in that the source region 1804 and the drain region 1806 are planar with respect to the substrate surface 1808.

FIG. 18B is a perspective view of an example FinFET transistor 1820 comprising a gate 1822 that controls current flow between a source region 1824 and a drain region 1826. The transistor 1820 is non-planar in that the source region 1824 and the drain region 1826 comprise “fins” that extend upwards from the substrate surface 1828. As the gate 1822 encompasses three sides of the semiconductor fin that extends from the source region 1824 to the drain region 1826, the transistor 1820 can be considered a tri-gate transistor. FIG. 18B illustrates one S/D fin extending through the gate 1822, but multiple S/D fins can extend through the gate of a FinFET transistor.

FIG. 18C is a perspective view of a gate-all-around (GAA) transistor 1840 comprising a gate 1842 that controls current flow between a source region 1844 and a drain region 1846. The transistor 1840 is non-planar in that the source region 1844 and the drain region 1846 are elevated from the substrate surface 1828.

FIG. 18D is a perspective view of a GAA transistor 1860 comprising a gate 1862 that controls current flow between multiple elevated source regions 1864 and multiple elevated drain regions 1866. The transistor 1860 is a stacked GAA transistor as the gate controls the flow of current between multiple elevated S/D regions stacked on top of each other. The transistors 1840 and 1860 are considered gate-all-around transistors as the gates encompass all sides of the semiconductor portions that extends from the source regions to the drain regions. The transistors 1840 and 1860 can alternatively be referred to as nanowire, nanosheet, or nanoribbon transistors depending on the width (e.g., widths 1848 and 1868 of transistors 1840 and 1860, respectively) of the semiconductor portions extending through the gate.

Returning to FIG. 17, a transistor 1740 may include a gate 1722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1740 along the source-channel-drain direction, the gate electrode may consist of a U-shaped structure that includes a bottom portion substantially parallel to the surface of the die substrate 1702 and two sidewall portions that are substantially perpendicular to the top surface of the die substrate 1702. In other embodiments, at least one of the metal layers that form the gate electrode may simply be a planar layer that is substantially parallel to the top surface of the die substrate 1702 and does not include sidewall portions substantially perpendicular to the top surface of the die substrate 1702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1720 may be formed within the die substrate 1702 adjacent to the gate 1722 of individual transistors 1740. The S/D regions 1720 may be formed using an implantation/diffusion process or an etching/deposition process, for example. In the former process, dopants such as boron, aluminum, antimony, phosphorous, or arsenic may be ion-implanted into the die substrate 1702 to form the S/D regions 1720. An annealing process that activates the dopants and causes them to diffuse farther into the die substrate 1702 may follow the ion-implantation process. In the latter process, the die substrate 1702 may first be etched to form recesses at the locations of the S/D regions 1720. An epitaxial deposition process may then be carried out to fill the recesses with material that is used to fabricate the S/D regions 1720. In some implementations, the S/D regions 1720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1720 may be formed using one or more alternate semiconductor materials such as germanium or a group III-V material or alloy. In further embodiments, one or more layers of metal and/or metal alloys may be used to form the S/D regions 1720.

Electrical signals, such as power and/or input/output (I/O) signals, may be routed to and/or from the devices (e.g., transistors 1740) of the device layer 1704 through one or more interconnect layers disposed on the device layer 1704 (illustrated in FIG. 17 as interconnect layers 1706-1710). For example, electrically conductive features of the device layer 1704 (e.g., the gate 1722 and the S/D contacts 1724) may be electrically coupled with the interconnect structures 1728 of the interconnect layers 1706-1710. The one or more interconnect layers 1706-1710 may form a metallization stack (also referred to as an “ILD stack”) 1719 of the integrated circuit device 1700.

The interconnect structures 1728 may be arranged within the interconnect layers 1706-1710 to route electrical signals according to a wide variety of designs; in particular, the arrangement is not limited to the particular configuration of interconnect structures 1728 depicted in FIG. 17. Although a particular number of interconnect layers 1706-1710 is depicted in FIG. 17, embodiments of the present disclosure include integrated circuit devices having more or fewer interconnect layers than depicted.

In some embodiments, the interconnect structures 1728 may include lines 1728a and/or vias 1728b filled with an electrically conductive material such as a metal. The lines 1728a may be arranged to route electrical signals in a direction of a plane that is substantially parallel with a surface of the die substrate 1702 upon which the device layer 1704 is formed. For example, the lines 1728a may route electrical signals in a direction in and out of the page and/or in a direction across the page. The vias 1728b may be arranged to route electrical signals in a direction of a plane that is substantially perpendicular to the surface of the die substrate 1702 upon which the device layer 1704 is formed. In some embodiments, the vias 1728b may electrically couple lines 1728a of different interconnect layers 1706-1710 together.

The interconnect layers 1706-1710 may include a dielectric material 1726 disposed between the interconnect structures 1728, as shown in FIG. 17. In some embodiments, dielectric material 1726 disposed between the interconnect structures 1728 in different ones of the interconnect layers 1706-1710 may have different compositions; in other embodiments, the composition of the dielectric material 1726 between different interconnect layers 1706-1710 may be the same. The device layer 1704 may include a dielectric material 1726 disposed between the transistors 1740 and a bottom layer of the metallization stack as well. The dielectric material 1726 included in the device layer 1704 may have a different composition than the dielectric material 1726 included in the interconnect layers 1706-1710; in other embodiments, the composition of the dielectric material 1726 in the device layer 1704 may be the same as a dielectric material 1726 included in any one of the interconnect layers 1706-1710.

A first interconnect layer 1706 (referred to as Metal 1 or “M1”) may be formed directly on the device layer 1704. In some embodiments, the first interconnect layer 1706 may include lines 1728a and/or vias 1728b, as shown. The lines 1728a of the first interconnect layer 1706 may be coupled with contacts (e.g., the S/D contacts 1724) of the device layer 1704. The vias 1728b of the first interconnect layer 1706 may be coupled with the lines 1728a of a second interconnect layer 1708.

The second interconnect layer 1708 (referred to as Metal 2 or “M2”) may be formed directly on the first interconnect layer 1706. In some embodiments, the second interconnect layer 1708 may include via 1728b to couple the lines 1728 of the second interconnect layer 1708 with the lines 1728a of a third interconnect layer 1710. Although the lines 1728a and the vias 1728b are structurally delineated with a line within individual interconnect layers for the sake of clarity, the lines 1728a and the vias 1728b may be structurally and/or materially contiguous (e.g., simultaneously filled during a dual-damascene process) in some embodiments.

The third interconnect layer 1710 (referred to as Metal 3 or “M3”) (and additional interconnect layers, as desired) may be formed in succession on the second interconnect layer 1708 according to similar techniques and configurations described in connection with the second interconnect layer 1708 or the first interconnect layer 1706. In some embodiments, the interconnect layers that are “higher up” in the metallization stack 1719 in the integrated circuit device 1700 (i.e., farther away from the device layer 1704) may be thicker that the interconnect layers that are lower in the metallization stack 1719, with lines 1728a and vias 1728b in the higher interconnect layers being thicker than those in the lower interconnect layers.

The integrated circuit device 1700 may include a solder resist material 1734 (e.g., polyimide or similar material) and one or more conductive contacts 1736 formed on the interconnect layers 1706-1710. In FIG. 17, the conductive contacts 1736 are illustrated as taking the form of bond pads. The conductive contacts 1736 may be electrically coupled with the interconnect structures 1728 and configured to route the electrical signals of the transistor(s) 1740 to external devices. For example, solder bonds may be formed on the one or more conductive contacts 1736 to mechanically and/or electrically couple an integrated circuit die including the integrated circuit device 1700 with another component (e.g., a printed circuit board). The integrated circuit device 1700 may include additional or alternate structures to route the electrical signals from the interconnect layers 1706-1710; for example, the conductive contacts 1736 may include other analogous features (e.g., posts) that route the electrical signals to external components.

In some embodiments in which the integrated circuit device 1700 is a double-sided die, the integrated circuit device 1700 may include another metallization stack (not shown) on the opposite side of the device layer(s) 1704. This metallization stack may include multiple interconnect layers as discussed above with reference to the interconnect layers 1706-1710, to provide conductive pathways (e.g., including conductive lines and vias) between the device layer(s) 1704 and additional conductive contacts (not shown) on the opposite side of the integrated circuit device 1700 from the conductive contacts 1736.

In other embodiments in which the integrated circuit device 1700 is a double-sided die, the integrated circuit device 1700 may include one or more through silicon vias (TSVs) through the die substrate 1702; these TSVs may make contact with the device layer(s) 1704, and may provide conductive pathways between the device layer(s) 1704 and additional conductive contacts (not shown) on the opposite side of the integrated circuit device 1700 from the conductive contacts 1736. In some embodiments, TSVs extending through the substrate can be used for routing power and ground signals from conductive contacts on the opposite side of the integrated circuit device 1700 from the conductive contacts 1736 to the transistors 1740 and any other components integrated into the die 1700, and the metallization stack 1719 can be used to route I/O signals from the conductive contacts 1736 to transistors 1740 and any other components integrated into the die 1700.

Multiple integrated circuit devices 1700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

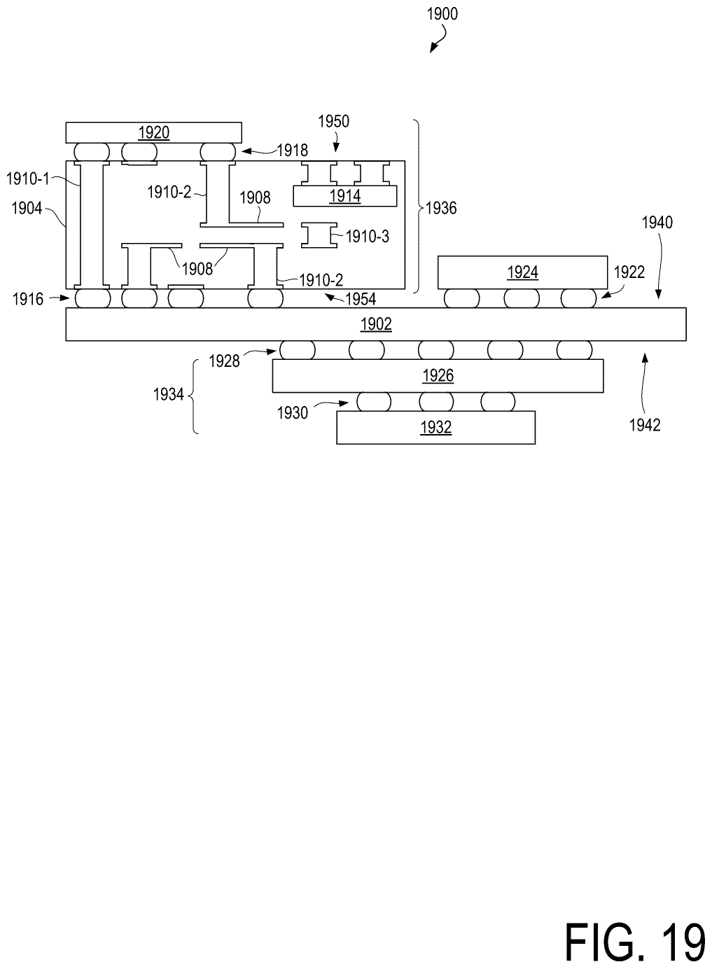

FIG. 19 is a cross-sectional side view of an integrated circuit device assembly 1900 that may include any of the transistors 100, 900 disclosed herein. The integrated circuit device assembly 1900 includes a number of components disposed on a circuit board 1902 (which may be a motherboard, system board, mainboard, etc.). The integrated circuit device assembly 1900 includes components disposed on a first face 1940 of the circuit board 1902 and an opposing second face 1942 of the circuit board 1902; generally, components may be disposed on one or both faces 1940 and 1942.

In some embodiments, the circuit board 1902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1902. In other embodiments, the circuit board 1902 may be a non-PCB substrate. The integrated circuit device assembly 1900 illustrated in FIG. 19 includes a package-on-interposer structure 1936 coupled to the first face 1940 of the circuit board 1902 by coupling components 1916. The coupling components 1916 may electrically and mechanically couple the package-on-interposer structure 1936 to the circuit board 1902, and may include solder balls (as shown in FIG. 19), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1936 may include an integrated circuit component 1920 coupled to an interposer 1904 by coupling components 1918. The coupling components 1918 may take any suitable form for the application, such as the forms discussed above with reference to the coupling components 1916. Although a single integrated circuit component 1920 is shown in FIG. 19, multiple integrated circuit components may be coupled to the interposer 1904; indeed, additional interposers may be coupled to the interposer 1904. The interposer 1904 may provide an intervening substrate used to bridge the circuit board 1902 and the integrated circuit component 1920.

The integrated circuit component 1920 may be a packaged or unpacked integrated circuit product that includes one or more integrated circuit dies (e.g., the die 1602 of FIG. 16, the integrated circuit device 1700 of FIG. 17) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1920, a single monolithic integrated circuit die comprises solder bumps attached to contacts on the die. The solder bumps allow the die to be directly attached to the interposer 1904. The integrated circuit component 1920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1904 may spread connections to a wider pitch or reroute a connection to a different connection. For example, the interposer 1904 may couple the integrated circuit component 1920 to a set of ball grid array (BGA) conductive contacts of the coupling components 1916 for coupling to the circuit board 1902. In the embodiment illustrated in FIG. 19, the integrated circuit component 1920 and the circuit board 1902 are attached to opposing sides of the interposer 1904; in other embodiments, the integrated circuit component 1920 and the circuit board 1902 may be attached to a same side of the interposer 1904. In some embodiments, three or more components may be interconnected by way of the interposer 1904.

In some embodiments, the interposer 1904 may be formed as a PCB, including multiple metal layers separated from one another by layers of dielectric material and interconnected by electrically conductive vias. In some embodiments, the interposer 1904 may be formed of an epoxy resin, a fiberglass-reinforced epoxy resin, an epoxy resin with inorganic fillers, a ceramic material, or a polymer material such as polyimide. In some embodiments, the interposer 1904 may be formed of alternate rigid or flexible materials that may include the same materials described above for use in a semiconductor substrate, such as silicon, germanium, and other group III-V and group IV materials. The interposer 1904 may include metal interconnects 1908 and vias 1910, including but not limited to through hole vias 1910-1 (that extend from a first face 1950 of the interposer 1904 to a second face 1954 of the interposer 1904), blind vias 1910-2 (that extend from the first or second faces 1950 or 1954 of the interposer 1904 to an internal metal layer), and buried vias 1910-3 (that connect internal metal layers).

In some embodiments, the interposer 1904 can comprise a silicon interposer. Through silicon vias (TSV) extending through the silicon interposer can connect connections on a first face of a silicon interposer to an opposing second face of the silicon interposer. In some embodiments, an interposer 1904 comprising a silicon interposer can further comprise one or more routing layers to route connections on a first face of the interposer 1904 to an opposing second face of the interposer 1904.

The interposer 1904 may further include embedded devices 1914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1904. The package-on-interposer structure 1936 may take the form of any of the package-on-interposer structures known in the art. In embodiments where the interposer is a non-printed circuit board

The integrated circuit device assembly 1900 may include an integrated circuit component 1924 coupled to the first face 1940 of the circuit board 1902 by coupling components 1922. The coupling components 1922 may take the form of any of the embodiments discussed above with reference to the coupling components 1916, and the integrated circuit component 1924 may take the form of any of the embodiments discussed above with reference to the integrated circuit component 1920.

The integrated circuit device assembly 1900 illustrated in FIG. 19 includes a package-on-package structure 1934 coupled to the second face 1942 of the circuit board 1902 by coupling components 1928. The package-on-package structure 1934 may include an integrated circuit component 1926 and an integrated circuit component 1932 coupled together by coupling components 1930 such that the integrated circuit component 1926 is disposed between the circuit board 1902 and the integrated circuit component 1932. The coupling components 1928 and 1930 may take the form of any of the embodiments of the coupling components 1916 discussed above, and the integrated circuit components 1926 and 1932 may take the form of any of the embodiments of the integrated circuit component 1920 discussed above. The package-on-package structure 1934 may be configured in accordance with any of the package-on-package structures known in the art.

FIG. 20 is a block diagram of an example electrical device 2000 that may include one or more of the transistors 100, 900 disclosed herein. For example, any suitable ones of the components of the electrical device 2000 may include one or more of the integrated circuit device assemblies 1900, integrated circuit components 1920, integrated circuit devices 1700, or integrated circuit dies 1602 disclosed herein. A number of components are illustrated in FIG. 20 as included in the electrical device 2000, but any one or more of these components may be omitted or duplicated, as suitable for the application. In some embodiments, some or all of the components included in the electrical device 2000 may be attached to one or more motherboards mainboards, or system boards. In some embodiments, one or more of these components are fabricated onto a single system-on-a-chip (SoC) die.

Additionally, in various embodiments, the electrical device 2000 may not include one or more of the components illustrated in FIG. 20, but the electrical device 2000 may include interface circuitry for coupling to the one or more components. For example, the electrical device 2000 may not include a display device 2006, but may include display device interface circuitry (e.g., a connector and driver circuitry) to which a display device 2006 may be coupled. In another set of examples, the electrical device 2000 may not include an audio input device 2024 or an audio output device 2008, but may include audio input or output device interface circuitry (e.g., connectors and supporting circuitry) to which an audio input device 2024 or audio output device 2008 may be coupled.

The electrical device 2000 may include one or more processor units 2002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2000 may include a memory 2004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2004 may include memory that is located on the same integrated circuit die as the processor unit 2002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2000 can comprise one or more processor units 2002 that are heterogeneous or asymmetric to another processor unit 2002 in the electrical device 2000. There can be a variety of differences between the processing units 2002 in a system in terms of a spectrum of metrics of merit including architectural, microarchitectural, thermal, power consumption characteristics, and the like. These differences can effectively manifest themselves as asymmetry and heterogeneity among the processor units 2002 in the electrical device 2000.

In some embodiments, the electrical device 2000 may include a communication component 2012 (e.g., one or more communication components). For example, the communication component 2012 can manage wireless communications for the transfer of data to and from the electrical device 2000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2012 may operate in accordance with other wireless protocols in other embodiments. The electrical device 2000 may include an antenna 2022 to facilitate wireless communications and/or to receive other wireless communications (such as AM or FM radio transmissions).

In some embodiments, the communication component 2012 may manage wired communications, such as electrical, optical, or any other suitable communication protocols (e.g., IEEE 802.3 Ethernet standards). As noted above, the communication component 2012 may include multiple communication components. For instance, a first communication component 2012 may be dedicated to shorter-range wireless communications such as Wi-Fi or Bluetooth, and a second communication component 2012 may be dedicated to longer-range wireless communications such as global positioning system (GPS), EDGE, GPRS, CDMA, WiMAX, LTE, EV-DO, or others. In some embodiments, a first communication component 2012 may be dedicated to wireless communications, and a second communication component 2012 may be dedicated to wired communications.

The electrical device 2000 may include battery/power circuitry 2014. The battery/power circuitry 2014 may include one or more energy storage devices (e.g., batteries or capacitors) and/or circuitry for coupling components of the electrical device 2000 to an energy source separate from the electrical device 2000 (e.g., AC line power).

The electrical device 2000 may include a display device 2006 (or corresponding interface circuitry, as discussed above). The display device 2006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2000 may include an audio output device 2008 (or corresponding interface circuitry, as discussed above). The audio output device 2008 may include any embedded or wired or wirelessly connected external device that generates an audible indicator, such speakers, headsets, or earbuds.

The electrical device 2000 may include an audio input device 2024 (or corresponding interface circuitry, as discussed above). The audio input device 2024 may include any embedded or wired or wirelessly connected device that generates a signal representative of a sound, such as microphones, microphone arrays, or digital instruments (e.g., instruments having a musical instrument digital interface (MIDI) output). The electrical device 2000 may include a Global Navigation Satellite System (GNSS) device 2018 (or corresponding interface circuitry, as discussed above), such as a Global Positioning System (GPS) device. The GNSS device 2018 may be in communication with a satellite-based system and may determine a geolocation of the electrical device 2000 based on information received from one or more GNSS satellites, as known in the art.

The electrical device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The electrical device 2000 may include an other input device 2020 (or corresponding interface circuitry, as discussed above). Examples of the other input device 2020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2000 may be any other electronic device that processes data. In some embodiments, the electrical device 2000 may comprise multiple discrete physical components. Given the range of devices that the electrical device 2000 can be manifested as in various embodiments, in some embodiments, the electrical device 2000 can be referred to as a computing device or a computing system.

### Examples

Illustrative examples of the technologies disclosed herein are provided below. An embodiment of the technologies may include any one or more, and any combination of, the examples described below.

Example 1 includes a device comprising a field effect transistor (FET) comprising a plurality of fins; a plurality of spacers, wherein the plurality of spacers are interleaved with the plurality of fins; a dielectric layer adjacent the plurality of fins and the plurality of spacers; and a gate adjacent the dielectric layer.

Example 2 includes the subject matter of Example 1, and wherein the plurality of fins comprise lanthanum, barium, tin, and oxygen.

Example 3 includes the subject matter of any of Examples 1 and 2, and wherein the plurality of spacers comprise barium, tin, and oxygen.

Example 4 includes the subject matter of any of Examples 1-3, and wherein a density of lanthanum in the plurality of spacers is less than 10% of a density of lanthanum in the plurality of fins.

Example 5 includes the subject matter of any of Examples 1-4, and wherein the plurality of spacers comprise a perovskite.

Example 6 includes the subject matter of any of Examples 1-5, and wherein the plurality of spacers comprise strontium, titanium, and oxygen.

Example 7 includes the subject matter of any of Examples 1-6, and wherein the plurality of spacers comprise strontium, ruthenium, and oxygen.

Example 8 includes the subject matter of any of Examples 1-7, and wherein the plurality of spacers comprise strontium, barium, ruthenium, and oxygen.

Example 9 includes the subject matter of any of Examples 1-8, and wherein the plurality of spacers comprise lanthanum, lutetium, and oxygen.

Example 10 includes the subject matter of any of Examples 1-9, and wherein the plurality of spacers comprise lanthanum, lutetium, scandium, and oxygen.

Example 11 includes the subject matter of any of Examples 1-10, and wherein the plurality of spacers comprise barium, scandium, niobium, and oxygen.

Example 12 includes the subject matter of any of Examples 1-11, and wherein the plurality of fins are a doped semiconductor and the plurality of spacers are an undoped semiconductor.

Example 13 includes the subject matter of any of Examples 1-12, and wherein a lattice constant of the plurality of spacers is within 3% of a lattice constant of the plurality of fins.

Example 14 includes the subject matter of any of Examples 1-13, and wherein a lattice constant of the plurality of spacers is 1%-5% larger than a lattice constant of the plurality of fins.

Example 15 includes the subject matter of any of Examples 1-14, and wherein the dielectric layer comprises a ferroelectric layer.

Example 16 includes the subject matter of any of Examples 1-15, and wherein the dielectric layer comprises an interlayer, wherein the interlayer is a linear dielectric, wherein the interlayer is adjacent the plurality of fins, wherein the ferroelectric layer is adjacent the interlayer, wherein the gate is adjacent the ferroelectric layer, wherein the interlayer bridges a lattice mismatch between the plurality of fins and the ferroelectric layer.

Example 17 includes the subject matter of any of Examples 1-16, and wherein the ferroelectric layer comprises barium, titanium, and oxygen.

Example 18 includes the subject matter of any of Examples 1-17, and wherein the ferroelectric layer comprises bismuth, iron, and oxygen.

Example 19 includes a processor comprising the device of any of Examples 1-18.

Example 20 includes a system comprising the processor of Example 19 and one or more memory devices.

Example 21 includes a method comprising depositing a semiconductor stack, wherein the semiconductor stack comprises a first plurality of layers and a second plurality of layers, wherein individual layers of the first plurality of layers are doped semiconductor layers, wherein the first plurality of layers alternate with the second plurality of layers; at least partially etching the second plurality of layers to create a plurality of fins from the first plurality of layers; depositing an insulating layer around part of the plurality of fins; and depositing a gate around part of the insulating layer.

Example 22 includes the subject matter of Example 21, and wherein at least partially etching the second plurality of layers comprises exposing the first plurality of layers and the second plurality of layers to a wet etchant, wherein the wet etchant preferentially etches the second plurality of layers.

Example 23 includes the subject matter of any of Examples 21 and 22, and wherein the first plurality of layers comprise lanthanum, barium, tin, and oxygen.

Example 24 includes the subject matter of any of Examples 21-23, and wherein the second plurality of layers comprise barium, tin, and oxygen.

Example 25 includes the subject matter of any of Examples 21-24, and wherein at least partially etching the second plurality of layers comprises exposing the first plurality of layers and the second plurality of layers to a wet etchant, wherein the wet etchant preferentially etches the second plurality of layers, wherein lanthanum in the first plurality of layers slows etching of the first plurality of layers.

Example 26 includes the subject matter of any of Examples 21-25, and wherein a density of lanthanum in the second plurality of layers is less than 10% of a density of lanthanum in the first plurality of layers.

Example 27 includes the subject matter of any of Examples 21-26, and wherein the second plurality of layers comprise a perovskite.

Example 28 includes the subject matter of any of Examples 21-27, and wherein the second plurality of layers comprise strontium, titanium, and oxygen.

Example 29 includes the subject matter of any of Examples 21-28, and wherein the second plurality of layers comprise strontium, ruthenium, and oxygen.

Example 30 includes the subject matter of any of Examples 21-29, and wherein the second plurality of layers comprise strontium, barium, ruthenium, and oxygen.

Example 31 includes the subject matter of any of Examples 21-30, and wherein the second plurality of layers comprise lanthanum, lutetium, and oxygen.

Example 32 includes the subject matter of any of Examples 21-31, and wherein the second plurality of layers comprise lanthanum, lutetium, scandium, and oxygen.

Example 33 includes the subject matter of any of Examples 21-32, and wherein the second plurality of layers comprise barium, scandium, niobium, and oxygen.

Example 34 includes the subject matter of any of Examples 21-33, and wherein the first plurality of layers are a doped semiconductor and the second plurality of layers are an undoped semiconductor.

Example 35 includes the subject matter of any of Examples 21-34, and wherein a lattice constant of the second plurality of layers is within 3% of a lattice constant of the first plurality of layers.

Example 36 includes the subject matter of any of Examples 21-35, and wherein a lattice constant of the second plurality of layers is 1%-5% larger than a lattice constant of the first plurality of layers.

Example 37 includes the subject matter of any of Examples 21-36, and wherein the insulating layer comprises a ferroelectric layer.

Example 38 includes the subject matter of any of Examples 21-37, and wherein the insulating layer comprises an interlayer, wherein the interlayer is a linear dielectric, wherein the interlayer is adjacent the part of the plurality of fins, wherein the ferroelectric layer is adjacent the interlayer, wherein the gate is adjacent the ferroelectric layer, wherein the interlayer bridges a lattice mismatch between the plurality of fins and the ferroelectric layer.

Example 39 includes the subject matter of any of Examples 21-38, and wherein the ferroelectric layer comprises barium, titanium, and oxygen.

Example 40 includes the subject matter of any of Examples 21-39, and wherein the ferroelectric layer comprises bismuth, iron, and oxygen.

Example 41 includes a device comprising a transistor comprising a channel defined in a semiconductor layer; an interlayer adjacent the semiconductor layer; a ferroelectric layer adjacent the interlayer; and a gate adjacent the ferroelectric layer, wherein the interlayer bridges a lattice mismatch between the semiconductor layer and the ferroelectric layer.

Example 42 includes the subject matter of Example 41, and wherein the semiconductor layer comprises lanthanum barium, tin, and oxygen.

Example 43 includes the subject matter of any of Examples 41 and 42, and wherein the ferroelectric layer comprises barium, titanium, and oxygen.

Example 44 includes the subject matter of any of Examples 41-43, and wherein the ferroelectric layer comprises bismuth, iron, and oxygen.

Example 45 includes the subject matter of any of Examples 41-44, and wherein the semiconductor layer has a first lattice constant, the interlayer has a second lattice constant, and the ferroelectric layer has a third lattice constant, wherein the second lattice constant is smaller than the first lattice constant, wherein the third lattice constant is smaller than the first lattice constant.

Example 46 includes the subject matter of any of Examples 41-45, and wherein the third lattice constant is larger than the second lattice constant.

Example 47 includes the subject matter of any of Examples 41-46, and wherein the third lattice constant is within 3% of the second lattice constant.

Example 48 includes the subject matter of any of Examples 41-47, and wherein the interlayer comprises strontium, titanium, and oxygen.

Example 49 includes the subject matter of any of Examples 41-48, and wherein the interlayer comprises lanthanum, aluminum, and oxygen.

Example 50 includes the subject matter of any of Examples 41-49, and wherein the interlayer comprises yttrium, aluminum, and oxygen.

Example 51 includes the subject matter of any of Examples 41-50, and wherein the interlayer comprises lutetium, aluminum, and oxygen.

Example 52 includes the subject matter of any of Examples 41-51, and wherein an orientation of a lattice of the interlayer relative to a lattice of the semiconductor layer is rotated relative to a cube-on-cube lattice orientation.

Example 53 includes the subject matter of any of Examples 41-52, and wherein the semiconductor layer has a first lattice constant, the interlayer has a second lattice constant, and the ferroelectric layer has a third lattice constant, wherein the second lattice constant is larger than the first lattice constant, wherein the third lattice constant is smaller than the first lattice constant.

Example 54 includes the subject matter of any of Examples 41-53, and wherein the interlayer comprises magnesium and oxygen.

Example 55 includes the subject matter of any of Examples 41-54, and wherein the interlayer comprises magnesium, aluminum, and oxygen.

Example 56 includes the subject matter of any of Examples 41-55, and wherein the interlayer comprises barium and oxygen.

Example 57 includes the subject matter of any of Examples 41-56, and wherein the interlayer comprises strontium and oxygen.

Example 58 includes the subject matter of any of Examples 41-57, and wherein the semiconductor layer is a perovskite, wherein the ferroelectric layer is a perovskite.

Example 59 includes the subject matter of any of Examples 41-58, and wherein a direction of polarization of the ferroelectric layer depends on a strain of the ferroelectric layer.

Example 60 includes the subject matter of any of Examples 41-59, and wherein the interlayer causes the direction of polarization of the ferroelectric layer to be substantially perpendicular to a plane defined by the ferroelectric layer.

Example 61 includes a method comprising forming a transistor on a substrate, wherein forming the transistor comprises depositing a semiconductor layer; depositing an interlayer on top of the semiconductor layer; and depositing a ferroelectric layer on top of the interlayer, wherein the interlayer bridges a lattice mismatch between the semiconductor layer and the ferroelectric layer.

Example 62 includes the subject matter of Example 61, and wherein the semiconductor layer comprises lanthanum barium, tin, and oxygen.

Example 63 includes the subject matter of any of Examples 61 and 62, and wherein the ferroelectric layer comprises barium, titanium, and oxygen.

Example 64 includes the subject matter of any of Examples 61-63, and wherein the ferroelectric layer comprises bismuth, iron, and oxygen.

Example 65 includes the subject matter of any of Examples 61-64, and wherein the semiconductor layer has a first lattice constant, the interlayer has a second lattice constant, and the ferroelectric layer has a third lattice constant, wherein the second lattice constant is smaller than the first lattice constant, wherein the third lattice constant is smaller than the first lattice constant.

Example 66 includes the subject matter of any of Examples 61-65, and wherein the third lattice constant is larger than the second lattice constant.

Example 67 includes the subject matter of any of Examples 61-66, and wherein the third lattice constant is within 3% of the second lattice constant.

Example 68 includes the subject matter of any of Examples 61-67, and wherein the interlayer comprises strontium, titanium, and oxygen.

Example 69 includes the subject matter of any of Examples 61-68, and wherein the interlayer comprises lanthanum, aluminum, and oxygen.

Example 70 includes the subject matter of any of Examples 61-69, and wherein the interlayer comprises yttrium, aluminum, and oxygen.

Example 71 includes the subject matter of any of Examples 61-70, and wherein the interlayer comprises lutetium, aluminum, and oxygen.

Example 72 includes the subject matter of any of Examples 61-71, and wherein an orientation of a lattice of the interlayer relative to a lattice of the semiconductor layer is rotated relative to a cube-on-cube lattice orientation.

Example 73 includes the subject matter of any of Examples 61-72, and wherein the semiconductor layer has a first lattice constant, the interlayer has a second lattice constant, and the ferroelectric layer has a third lattice constant, wherein the second lattice constant is larger than the first lattice constant, wherein the third lattice constant is smaller than the first lattice constant.

Example 74 includes the subject matter of any of Examples 61-73, and wherein the interlayer comprises magnesium and oxygen.

Example 75 includes the subject matter of any of Examples 61-74, and wherein the interlayer comprises magnesium, aluminum, and oxygen.

Example 76 includes the subject matter of any of Examples 61-75, and wherein the interlayer comprises barium and oxygen.

Example 77 includes the subject matter of any of Examples 61-76, and wherein the interlayer comprises strontium and oxygen.

Example 78 includes the subject matter of any of Examples 61-77, and wherein the semiconductor layer is a perovskite, wherein the ferroelectric layer is a perovskite.

Example 79 includes the subject matter of any of Examples 61-78, and wherein a direction of polarization of the ferroelectric layer depends on a strain of the ferroelectric layer.

Example 80 includes the subject matter of any of Examples 61-79, and wherein the interlayer causes the direction of polarization of the ferroelectric layer to be substantially perpendicular to a plane defined by the ferroelectric layer.

1. A device comprising:
a field effect transistor (FET) comprising:
a plurality of fins;
a plurality of spacers, wherein the plurality of spacers are interleaved with the plurality of fins;
a dielectric layer adjacent the plurality of fins and the plurality of spacers; and
a gate adjacent the dielectric layer.

2. The device of claim 1, wherein the plurality of fins comprise lanthanum, barium, tin, and oxygen.

3. The device of claim 2, wherein the plurality of spacers comprise barium, tin, and oxygen.

4. The device of claim 3, wherein a density of lanthanum in the plurality of spacers is less than 10% of a density of lanthanum in the plurality of fins.

5. The device of claim 1, wherein the plurality of fins are a doped semiconductor and the plurality of spacers are an undoped semiconductor.

6. The device of claim 1, wherein the dielectric layer comprises a ferroelectric layer.

7. The device of claim 6, wherein the dielectric layer comprises an interlayer, wherein the interlayer is a linear dielectric,
wherein the interlayer is adjacent the plurality of fins,
wherein the ferroelectric layer is adjacent the interlayer,
wherein the gate is adjacent the ferroelectric layer,
wherein the interlayer bridges a lattice mismatch between the plurality of fins and the ferroelectric layer.

8. A processor comprising the device of claim 1.

9. A method comprising:
depositing a semiconductor stack, wherein the semiconductor stack comprises a first plurality of layers and a second plurality of layers, wherein individual layers of the first plurality of layers are doped semiconductor layers, wherein the first plurality of layers alternate with the second plurality of layers;
at least partially etching the second plurality of layers to create a plurality of fins from the first plurality of layers;
depositing an insulating layer around part of the plurality of fins; and
depositing a gate around part of the insulating layer.

10. The method of claim 9, wherein at least partially etching the second plurality of layers comprises exposing the first plurality of layers and the second plurality of layers to a wet etchant, wherein the wet etchant preferentially etches the second plurality of layers.

11. The method of claim 9, wherein the first plurality of layers comprise lanthanum, barium, tin, and oxygen.

12. The method of claim 11, wherein the second plurality of layers comprise barium, tin, and oxygen.

13. The method of claim 12, wherein at least partially etching the second plurality of layers comprises exposing the first plurality of layers and the second plurality of layers to a wet etchant, wherein the wet etchant preferentially etches the second plurality of layers, wherein lanthanum in the first plurality of layers slows etching of the first plurality of layers.

14. The method of claim 12, wherein a density of lanthanum in the second plurality of layers is less than 10% of a density of lanthanum in the first plurality of layers.

15. The method of claim 9, wherein the first plurality of layers are a doped semiconductor and the second plurality of layers are an undoped semiconductor.

16. The method of claim 9, wherein the insulating layer comprises a ferroelectric layer.

17. The method of claim 16, wherein the insulating layer comprises an interlayer, wherein the interlayer is a linear dielectric,
wherein the interlayer is adjacent the part of the plurality of fins,
wherein the ferroelectric layer is adjacent the interlayer,
wherein the gate is adjacent the ferroelectric layer,
wherein the interlayer bridges a lattice mismatch between the plurality of fins and the ferroelectric layer.

18. A device comprising:
a transistor comprising:
a channel defined in a semiconductor layer;
an interlayer adjacent the semiconductor layer;
a ferroelectric layer adjacent the interlayer; and
a gate adjacent the ferroelectric layer,
wherein the interlayer bridges a lattice mismatch between the semiconductor layer and the ferroelectric layer.

19. The device of claim 18, wherein the semiconductor layer comprises lanthanum barium, tin, and oxygen.

20. The device of claim 19, wherein the ferroelectric layer comprises barium, titanium, and oxygen.

21. The device of claim 19, wherein the ferroelectric layer comprises bismuth, iron, and oxygen.

22. The device of claim 18, wherein the semiconductor layer has a first lattice constant, the interlayer has a second lattice constant, and the ferroelectric layer has a third lattice constant,
wherein the second lattice constant is smaller than the first lattice constant, wherein the third lattice constant is smaller than the first lattice constant.

23. The device of claim 18, wherein an orientation of a lattice of the interlayer relative to a lattice of the semiconductor layer is rotated relative to a cube-on-cube lattice orientation.

24. The device of claim 18, wherein a direction of polarization of the ferroelectric layer depends on a strain of the ferroelectric layer.

25. The device of claim 24, wherein the interlayer causes the direction of polarization of the ferroelectric layer to be substantially perpendicular to a plane defined by the ferroelectric layer.
